(19) United States
(12) Patent Application Publication
(10) Pub. No.: US 2026/0341390 A1
(43) Pub. Date: Oct. 29, 2026

(54) ESTIMATING A SYNDROME WEIGHT FOR A READ THRESHOLD CALIBRATION OPERATION

(71) Applicant: Sandisk Technologies, Inc., Milpitas, CA (US)

(72) Inventors: Yoav Porat, Be'er Sheva (IL); Alexander Bazarsky, Amsterdam (NL); Ran Zamir, Ramat Gan (IL)

(21) Appl. No.: 19/187,574

(22) Filed: Apr. 23, 2025

(51) Int. Cl. G11C 29/52; G11C 29/02

(52) U.S. Cl. CPC G11C 29/52; G11C 29/028

(57) ABSTRACT

A data storage device includes a syndrome weight estimation system that estimates partial syndrome weights, instead of full syndrome weights, during a read threshold calibration operation. During traversal of a bipartite graph associated with a decoding operation, the syndrome weight estimation system determines whether a codeword that is read with a particular read threshold voltage has an accumulated syndrome weight over a syndrome weight threshold. If the syndrome weight estimation system determines that the accumulated syndrome weight is over the syndrome weight threshold, further syndrome weight calculations for that particular read threshold voltage are stopped and the accumulated syndrome weight is returned to an ECC system.

### BACKGROUND

A data storage device, such as a NAND data storage device, stores data by maintaining specific charge levels within one or more memory cells. During a read operation, a controller of the data storage device compares a charge level of one or more memory cells against one or more predefined read threshold voltages to determine the value of the stored data.

However, over time, the electrical characteristics of memory cells can change due to various factors, including repeated program/erase cycling, data retention, disturb effects, environmental conditions, and operational stress. These changes can lead to shifts in the charge levels, making it difficult to accurately distinguish between stored values using the original read threshold voltages. As a result, read data exhibits increased bit error rates (BERs) which results in longer decoding latency, higher decoder power consumption and may even lead to decoding failures.

To mitigate these issues, a read threshold calibration operation may be performed on the data storage device. The read threshold calibration operation adjusts the one or more predefined read threshold voltages that are used during read operations to align read threshold voltages with the current state of the memory cells. By calibrating the read threshold voltages, error rates are reduced, which improves data reliability and can extend the usable life of the data storage device.

Typical read threshold calibration operations determine a syndrome weight that represents the accuracy of the data that is being read. For example, as the read threshold voltages are adjusted as part of the read threshold calibration operation, the data is read using the adjusted read threshold voltages and a syndrome weight is calculated. If the syndrome weight is high, the adjusted read threshold voltage may be too high or too low. As such, different read threshold voltages may be selected and used to lower the syndrome weight.

However, calculating the syndrome weight for each adjusted read threshold voltage is time consuming and may increase the latency of the read threshold calibration operation and increase the power consumption of the data storage device. As a result, a quality of service (QoS) and a throughput of the data storage device may be negatively impacted.

Accordingly, it would be beneficial to improve how a syndrome weight is calculated as part of a read threshold calibration operation.

Examples of the present disclosure describe a data storage device, such as, for example, a NAND data storage device, that includes an error correction code (ECC) system and a syndrome weight estimation system. In an example, the ECC system and the syndrome weight estimation system calculate, or estimate, partial syndrome weights, instead of full syndrome weights, during a read threshold calibration operation.

Since the goal of the read threshold calibration operation is to find read thresholds that provide the lowest syndrome weight, the syndrome weight estimation system determines whether data that is read with a particular read threshold voltage combination has an accumulated syndrome weight over a syndrome weight threshold. If the syndrome weight estimation system determines the accumulated syndrome weight is over the syndrome weight threshold, further syndrome weight calculations for that particular read threshold voltage combination are stopped.

For example, the syndrome weight estimation system determines or calculates a syndrome weight for a particular read threshold voltage combination during one traversal of a low-density parity check (LDPC) bipartite graph. If the calculated or accumulated syndrome weight over that traversal is above the syndrome weight threshold, the syndrome weight estimation system stops additional syndrome weight calculations for the read threshold voltage combination. The syndrome weight estimation system may also mark or identify the read threshold voltage combination as being excluded as an optimal read threshold voltage candidate. The syndrome weight estimation system may also associate a predetermined syndrome weight value with the read threshold voltage combination. As such, syndrome weight calculations will be shorter when compared with current solutions, which will improve the quality of service (QoS) of the data storage device by improving throughput and reducing overall power consumption.

Although a read threshold calibration operation is specifically mentioned, the ECC system and/or the syndrome weight estimation system can calculate or estimate partial syndrome weights during decoding operations, or other operations, in which a syndrome weight is typically calculated and/or used.

Accordingly, examples of the present disclosure describe a method that includes receiving, from a requesting system, a syndrome weight estimation request. In an example, the syndrome weight estimation request is associated with a particular read threshold voltage combination and a codeword. A parameter associated with the syndrome weight estimation request is also received. A parity check is executed on a check node associated with the codeword and a determination is made as to whether the parameter associated with the syndrome weight estimation request is satisfied based, at least in part, on the parity check on the check node. Based, at least in part, on determining that the parameter associated with the syndrome weight estimation request is satisfied, the execution of additional parity checks is stopped and an estimated syndrome weight is provided to the requesting system.

The present disclosure also describes a data storage device that includes a controller and a syndrome weight estimation system associated with the controller. The syndrome weight estimation system is operable to receive a syndrome weight estimation request and receive a parameter associated with the syndrome weight estimation request. The syndrome weight estimation system executes a syndrome weight determination operation to determine whether the parameter associated with the syndrome weight estimation request is satisfied during the execution of the syndrome weight determination operation. Based, at least in part, on the syndrome weight estimation system determining that the parameter associated with the syndrome weight estimation request is satisfied, the syndrome weight estimation system stops execution the syndrome weight determination operation and returns an estimated syndrome weight to a requesting device.

Other examples of the present disclosure describe a data storage device that includes means for receiving a syndrome weight estimation request and means for receiving a parameter associated with the syndrome weight estimation request. The data storage device also includes means for executing a syndrome weight determination operation and means for determining whether an accumulated syndrome weight exceeds the parameter associated with the syndrome weight estimation request during the syndrome weight determination operation. The data storage device also includes means for stopping execution of the syndrome weight determination operation. In an example, the means for stopping the execution of the syndrome weight determination operation stops the execution of the syndrome weight determination operation based, at least in part, on a determination that the parameter associated with the syndrome weight estimation request is satisfied.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a block diagram of a system that includes a host device and a data storage device according to an example.

FIG. 2A illustrates a bipartite graph that may be used in a parity check operation according to an example.

FIG. 2B illustrates a bipartite graph that may be used in a parity check operation according to another example.

FIG. 3 illustrates a method for estimating a syndrome weight of a read threshold voltage according to an example.

FIG. 4 illustrates a method for estimating a syndrome weight of a read threshold voltage according to another example.

FIG. 5 illustrates a method for estimating a syndrome weight of a read threshold voltage according to another example.

FIG. 6 is a perspective view of a storage device that includes three-dimensional (3D) stacked non-volatile memory according to an example.

FIG. 7 is a block diagram of a storage device according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

As previously described, a data storage device stores data by maintaining specific charge levels within one or more memory cells. During a read operation, a controller of the data storage device compares a charge level of one or more memory cells against one or more predefined read threshold voltages to determine the value of the stored data.

However, over time, the electrical characteristics of memory cells can change due to various factors. These changes can lead to shifts in the charge levels, making it difficult to accurately distinguish between stored values using the originally configured read threshold voltages. To mitigate these issues, a read threshold calibration operation can be performed on the data storage device. The read threshold calibration operation adjusts the reference read threshold voltages that are used during read operations to align with the current state of the memory cells.

Typical read threshold calibration operations determine a syndrome weight that represents the BER of the read data. For example, an ECC system of the data storage device varies the read threshold voltages that are used to read data stored by the data storage device and checks for errors by comparing the data that was read to what was expected. For each read threshold voltage variation, the ECC system calculates a syndrome weight, which provides a quantitative measure of the accuracy of the data.

For example, the ECC system feeds the read data though a parity-check matrix. If the result of the comparison, or the syndrome, is all zeros (“0s”), the data is most likely error free. However, if the result includes non-zero bits (e.g., “1s”), there are errors in the data. Thus, if the syndrome weight is high (e.g., there are a lot of ones in the syndrome), the read threshold voltage is likely too high or too low. However, if the syndrome weight is low (e.g., there are few, if any, ones in the syndrome), the read threshold voltage is likely optimal.

The goal of any read threshold calibration operation is to search for read threshold voltages that provide the lowest syndrome weight and/or have a syndrome weight that is within a correctable bit error rate (BER) range of a decoder of the data storage device. However, a read threshold calibration operation typically uses a number of different read threshold voltage combinations, some of which are far from an optimal read threshold voltage. Thus, a data storage device may unnecessarily use or expend a lot of resources determining an actual syndrome weight for each read threshold voltage combination in a read threshold calibration operation.

To address the above, the present disclosure describes a syndrome weight estimation system for a data storage device. In an example, the syndrome weight estimation system is part of, or otherwise associated with, an error correction code (ECC) system of the data storage device. The syndrome weight estimation system is operable to calculate partial syndrome weights, instead of full syndrome weights, during a read threshold calibration operation. Although a read threshold calibration operation is specifically mentioned, the syndrome weight estimation system can calculate or estimate partial syndrome weights during decoding operations, or other operations, in which a syndrome weight is typically calculated and/or used.

In an example and as will be described in greater detail herein, the syndrome weight estimation system determines, during a read threshold calibration operation, whether data that is read with a particular read threshold voltage combination has an accumulated syndrome weight over a syndrome weight threshold. If the syndrome weight estimation system determines that the accumulated syndrome weight is over the syndrome weight threshold, further syndrome weight calculations for that particular read threshold voltage are stopped.

For example, the syndrome weight estimation system determines or calculates a syndrome weight for a particular read threshold voltage combination during traversal of a low-density parity check (LDPC) bipartite graph. Each time one of the check nodes of the parity check is not satisfied, a syndrome weight counter is incremented to generate an accumulated syndrome weight. If the accumulated syndrome weight over that traversal is above the syndrome weight threshold, the syndrome weight estimation system stops additional syndrome weight calculations for the read threshold voltage and marks or identifies the read threshold voltage combination as being excluded as an optimal read threshold candidate. Determining a partial syndrome weight calculation is shorter when compared with determining full or conventional syndrome weight calculations. As a result, many technical benefits will be realized including increasing the QoS of the data storage device, including improving throughput while reducing overall power consumption of the data storage device.

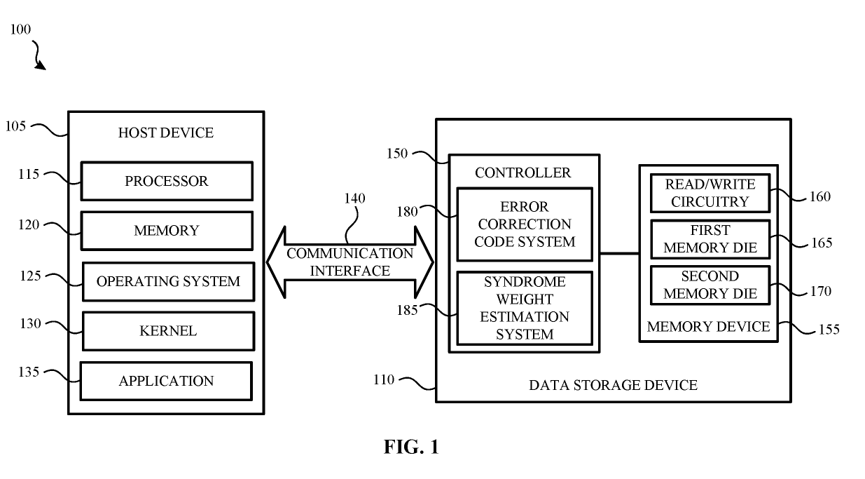

These benefits, along with other examples, will be shown and described in greater detail with respect to FIGS. 1-7 .

FIG. 1 is a block diagram of a system 100 that includes a host device 105 and a data storage device 110 according to an example. In an example, the host device 105 includes a processor 115 and a memory 120 (e.g., main memory). The memory 120 may include or otherwise be associated with an operating system 125, a kernel 130 and/or an application 135.

The processor 115 can execute various instructions, such as, for example, instructions from the operating system 125 and/or the application 135. The processor 115 includes circuitry such as a microcontroller, a Digital Signal Processor (DSP), an Application-Specific Integrated Circuit (ASIC), a Field Programmable Gate Array (FPGA), hard-wired logic, analog circuitry and/or various combinations thereof. In an example, the processor 115 includes a System on a Chip (SoC).

In an example, the memory 120 is used by the host device 105 to store data that is used, or otherwise executed by, the processor 115. Data stored in the memory 120 includes instructions provided by the data storage device 110 via a communication interface 140. The data stored in the memory 120 also includes data used to execute instructions from the operating system 125 and/or one or more applications 135. In an example, the memory 120 is a single memory. In another example, the memory 120 includes multiple memories, such as, for example, one or more non-volatile memories, one or more volatile memories, or a combination thereof.

In an example, the operating system 125 creates a virtual address space for the application 135 and/or other processes executed by the processor 115. The virtual address space maps to locations in the memory 120. The operating system 125 also includes, or is otherwise associated with, a kernel 130. In an example, the kernel 130 includes instructions for managing various resources of the host device 105 (e.g., memory allocation), handling read and write requests and performing other operations.

The communication interface 140 communicatively couples the host device 105 and the data storage device 110. The communication interface 140 may be a Serial Advanced Technology Attachment (SATA), a PCI express (PCIe) bus, a Small Computer System Interface (SCSI), a Serial Attached SCSI (SAS), Ethernet, Fibre Channel, or Wi-Fi. As such, the host device 105 and the data storage device 110 need not be physically co-located and may communicate over a network such as a Local Area Network (LAN) or a Wide Area Network (WAN), such as the internet. In addition, the host device 105 interfaces with the data storage device 110 using a logical interface specification such as Non-Volatile Memory express (NVMe) or Advanced Host Controller Interface (AHCI).

The data storage device 110 also includes a controller 150 and a memory device 155. In an example, the controller 150 is communicatively coupled to the memory device 155. The memory device 155 includes one or more memory dies (e.g., first memory die 165 and second memory die 170). Although memory dies are specifically mentioned, the memory device 155 may include any non-volatile memory device, storage device, storage elements or storage medium including NAND flash memory cells and/or NOR flash memory cells.

The memory cells can take the form of solid-state (e.g., flash) memory cells and can be one-time programmable, few-time programmable, or many-time programmable. Additionally, the memory cells may be single-level cells (SLCs), multi-level cells (MLCs), triple-level cells (TLCs), quad-level cells (QLCs), penta-level cells (PLCs), and/or use any other memory technologies. The memory cells are arranged in a two-dimensional configuration or a three-dimensional configuration.

In some examples, the data storage device 110 is attached to or embedded within the host device 105. In another example, the data storage device 110 is implemented as an external device or a portable device that can be communicatively or selectively coupled to the host device 105. In yet another example, the data storage device 110 is a component (e.g., a solid-state drive (SSD)) of a network accessible data storage system, a network-attached storage system, a cloud data storage system, and the like.

As indicated above, the memory device 155 of the data storage device 110 includes a first memory die 165 and a second memory die 170. Although two memory dies are shown, the memory device 155 may include any number of memory dies (e.g., one memory die, two memory dies, eight memory dies, or another number of memory dies).

The memory device 155 also includes support circuitry. In an example, the support circuitry includes read/write circuitry 160. The read/write circuitry 160 supports the operation of the memory dies of the memory device 155. Although the read/write circuitry 160 is depicted as a single component, the read/write circuitry 160 may be divided into separate components, such as, for example, read circuitry and write circuitry. The read/write circuitry 160 may be external to the memory dies of the memory device 155. In another example, one or more of the memory dies include corresponding read/write circuitry 160 that is operable to read data from and/or write data to storage elements within one individual memory die independent of other read and/or write operations on any of the other memory dies.

In an example, one or more of the first memory die 165 and the second memory die 170 include one or more memory blocks. In an example, each memory block includes one or more memory cells. A block of memory cells is the smallest number of memory cells that are physically erasable together. In an example and for increased parallelism, each of the blocks may be operated or organized in larger blocks or metablocks. For example, one block from different planes of memory cells may be logically linked together to form a metablock.

As previously described, the data storage device 110 also includes at least one controller 150. Although a single controller 150 is shown and described, the data storage device 110 can include multiple controllers. In such example, a first controller performs a first operation or set of operations and a second controller performs a second operation or set of operations. The operations may be performed in parallel, substantially in parallel or in sequence.

The controller 150 is communicatively coupled to the memory device 155 via a bus, an interface or other communication circuitry. In an example, the communication circuitry includes one or more channels which enable the controller 150 to communicate with the first memory die 165 and/or the second memory die 170 of the memory device 155. In another example, the communication circuitry includes multiple distinct channels which enables the controller 150 to communicate with the first memory die 165 independently and/or in parallel with the second memory die 170 of the memory device 155.

The controller 150 receives data and/or instructions from the host device 105. The controller 150 may also send data to the host device 105. For example, the controller 150 may send data to and/or receive data from the host device 105 via the communication interface 140.

The controller 150 may also send data and/or commands to and/or receive data from the memory device 155. For example, the controller 150 sends data and a corresponding write command to the memory device 155 to cause the memory device 155 to store data at a specified address of the memory device 155. In an example, the write command specifies a physical address of a portion of the memory device 155. The controller 150 may also send one or more read commands to the memory device 155. In an example, the read command specifies the physical address of a portion of the memory device 155 at which the data is stored.

The controller 150 also includes or is otherwise associated with an error correction code (ECC) system 180 and a syndrome weight estimation system 185. Although the ECC system 180 and the syndrome weight estimation system 185 are shown separately, the ECC system 180 and the syndrome weight estimation system 185 may be integrated into a single system. Additionally, one or more of the ECC system 180 and the syndrome weight estimation system 185 may be packaged functional hardware units designed for use with other components/systems, a portion of a program code (e.g., software or firmware) executable by the controller 150, a processor and/or processing circuitry, or a self-contained hardware and/or software component that interfaces with other components and/or systems.

In an example, the ECC system 180 receives data to be stored to the memory device 155 and generates a codeword. For example, the ECC system 180 includes an encoder configured to encode data using an ECC encoding scheme, such as a Reed Solomon encoder, a Bose-Chaudhuri-Hocquenghem (BCH) encoder, a low-density parity check (LDPC) encoder, a Turbo Code encoder, an encoder configured to encode one or more other ECC encoding schemes, or any combination thereof. The ECC system 180 also includes a decoder that is operable to decode data read from the memory device 155. The decoder is operable to detect and correct, up to an error correction capability of the ECC scheme, any bit errors that may be present in data that is read from the memory device 155.

In an example, the ECC system 180 is also operable to perform one or more read threshold calibration operations to update one or more read threshold voltages based, at least in part, on information received from the decoder. In an example, the read threshold calibration is a bit error rate (BER) estimation scan (BES). In a BES operation, a series of reads are performed around one or more read threshold voltages to find an optimal read threshold voltage.

For example, during a BES operation a “hypothesis” is determined. The hypothesis represents a potential set of read threshold voltages for reading a page. The ECC system emulates (instead of physically sensing the memory dies in the memory device 155) what the resulting read page would be if the specific set of read threshold voltages was used and calculates a corresponding syndrome weight for the read page.

In an example, the syndrome weight is a proxy for the BER if the page were to be read using this set of read threshold voltages. The BES determines an optimal set of read threshold voltages by scanning the possible options for read threshold voltages and chooses the one which has a minimal (or a minimum) syndrome weight. The BES operation is explained in more detail in U.S. Patent Application No. 9,697,905, entitled Updating Read threshold voltages Using Syndrome Weight Comparisons, the entire disclosure of which is hereby incorporated by reference in its entirety. Although a BES operation is specifically mentioned, the various examples described herein may be used for any read threshold calibration operation and/or for any operations in which a syndrome weight is calculated or determined.

In an example, the ECC system 180 determines to execute a read threshold calibration operation, such as a BES operation, when one or more operating conditions of the data storage device 110 has been identified or detected. For example, the ECC system 180 may determine that a number of bit errors from read data exceeds a threshold. In another example, the ECC system 180 may execute the read threshold calibration operation periodically or after a threshold amount of time has passed. In yet another example, the ECC system 180 determines to execute the read threshold calibration operation after a particular number of program/erase (P/E) cycles have been performed. Although specific examples are given, these are for example purposes only and the ECC system 180 may execute the read calibration threshold operation for any number of reasons.

In an example, and when the read threshold calibration operation has been initiated and a syndrome weight calculation is needed (e.g., the syndrome weight for a particular read threshold voltage combination is needed to determine whether the particular read threshold voltage is a candidate for being an optimal read threshold voltage), the ECC system 180 provides a syndrome weight estimation request to the syndrome weight estimation system 185. The ECC system 180 may also provide a syndrome weight threshold to the syndrome weight estimation system 185.

In an example, the syndrome weight threshold is dynamic, and may be based, at least in part, on a desired or required read threshold accuracy. For example, when the read threshold accuracy is a first value (e.g., a high value) a first, higher syndrome weight threshold may be used and/or calculated. The higher syndrome weight threshold may result in a more accurate read threshold but longer calibration latency (when compared with a second, lower syndrome weight threshold). However, calibration needs to be performed quickly (e.g., for improved quality of service (QoS)), a second, lower syndrome weight threshold can be used. In an example, the second syndrome wight threshold may be faster when compared to examples in which the first syndrome weight threshold is used but may have a lower or reduced accuracy.

When the syndrome weight estimation request and/or the syndrome weight threshold are received, the syndrome weight estimation system 185 executes a parity check on a codeword and/or the data to determine which check nodes are unsatisfied (e.g., which check nodes in a bipartite graph correspond to a one (1)).

For example, during decoding, a bipartite graph is used to represent the structure of the data and to facilitate efficient decoding. The bipartite graph consists of two sets of nodes - variable nodes and check nodes. The variable nodes represent the bits of a codeword (including the stored data and associated parity bits). The check nodes represent parity-check equations. The variable nodes are connected to the check nodes using various edges that indicate which bits participate in which parity-check equations.

During decoding, the bipartite graph enables the variable nodes and the check nodes exchange reliability information. For example, the check nodes evaluate parity conditions based on the current values of connected variable nodes and send feedback that is used to update the estimates of the bits. Typically, this process continues until all parity checks are satisfied.

However, the syndrome weight estimation system 185 of the present disclosure traverses some or all of the bipartite graph one time and determines a syndrome weight after the traversal. For example, after each clock cycle in which one or more check nodes have been evaluated, the syndrome weight estimation system 185 determines an accumulated number check nodes (e.g., the accumulated number of ones (1s) for each check node) that are unsatisfied. This is referred to as the accumulated syndrome weight.

If the accumulated syndrome weight is above the syndrome weight threshold, the syndrome weight estimation system 185 stops further syndrome weight calculations for the particular read threshold voltage and codeword. The syndrome weight estimation system 185 also notifies the ECC system 180 that the particular read threshold voltage combination has caused the syndrome weight threshold to be exceeded. In response, the ECC system 180 marks or identifies the particular read threshold voltage combination as not being a candidate for an optimal read threshold voltage and/or associates a predetermined syndrome weight to the particular read threshold voltage combination. The process may then be repeated for another read threshold voltage combination.

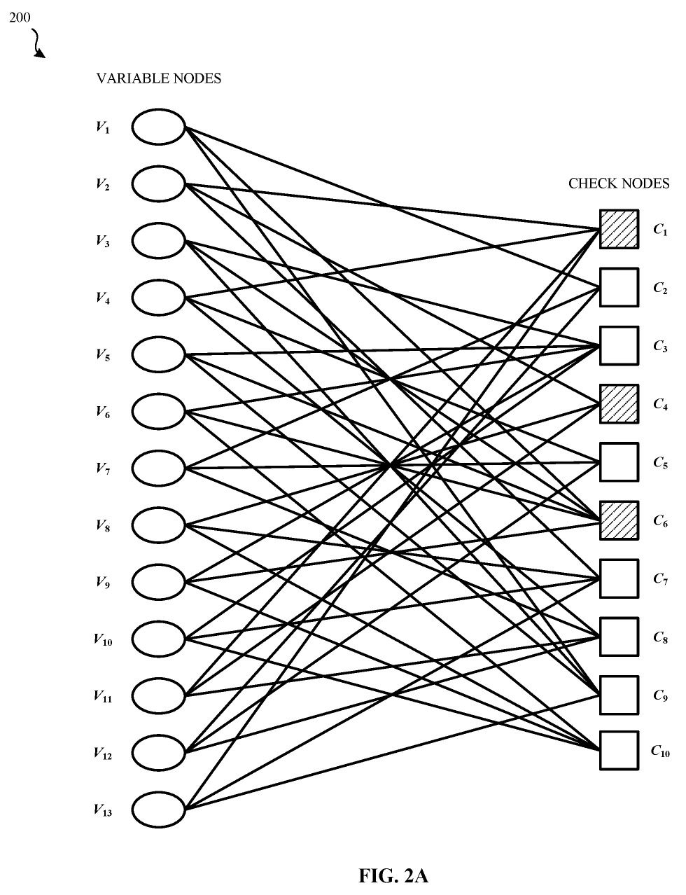

For example and referring to FIG. 2A, FIG. 2A illustrates a bipartite graph 200 that may be used in a parity check operation according to an example. As shown in FIG. 2A, the bipartite graph 200 includes a number of variable nodes (e.g., variable nodes V ₁ – V ₁₃) and a number of check nodes (C ₁ – C ₁₀). Various variable nodes are connected to various check nodes using one or more edges.

During a parity check operation, a syndrome weight estimation system, such as the syndrome weight estimation system 185 (FIG. 1), determines which check nodes are unsatisfied based on the variable nodes. For example, during a first clock cycle, the syndrome weight estimation system may analyze check nodes C₁ and C ₂ and determine check node C ₁ is unsatisfied (represented by the shading). As such, the syndrome weight estimation system will increment the accumulated syndrome weight and determine whether the accumulated syndrome weight is above the syndrome weight threshold. If the accumulated syndrome weight has not exceeded the syndrome weight threshold, the parity check for the particular read threshold voltage continues.

Continuing with the example, during a second clock cycle, the syndrome weight estimation system analyzes check nodes C ₃ and C ₄ and determines check node C ₄ is unsatisfied (represented by the shading). As such, the syndrome weight estimation system will increment the accumulated syndrome weight and determine whether the accumulated syndrome weight is above the syndrome weight threshold. In this example, the accumulated syndrome weight has not exceeded the syndrome weight threshold, so the parity check/syndrome weight estimation continues.

However, during a third clock cycle, the syndrome weight estimation system analyzes check nodes C ₅ and C ₆and determines check node C ₆ is unsatisfied (represented by the shading). As such, the syndrome weight estimation system increments the accumulated syndrome weight and determines that the accumulated syndrome weight is above the syndrome weight threshold. As such, the syndrome weight estimation system stops any further parity checks/syndrome weight calculations and notifies the ECC system.

When the ECC system receives the notification, the ECC system marks the particular read threshold as not being an optimal read threshold and associates a predetermined syndrome weight to the particular read threshold voltage. The ECC system may then select another read threshold voltage and codeword and the operations described above are repeated.

In another example, the syndrome weight estimation system may traverse the entire bipartite graph 200 and determine that the syndrome weight threshold is not exceeded. In such an example, the syndrome weight estimation system provides the calculated syndrome weight to the ECC system. As a result, the ECC system may mark or identify the particular read threshold voltage as a potential optimal read threshold voltage (e.g., depending on how the calculated syndrome weight compares against other calculated syndrome weights associated with other read threshold voltages). In an example, the potential optimal read threshold voltages are compared to determine which provide the best or maximum accuracy when compared with the other optimal read threshold voltages.

As previously described, the goal of the read threshold calibration operation is to search for read thresholds that provide the lowest syndrome weight. Thus, if a particular read threshold voltage combination causes the syndrome weight to exceed the syndrome weight threshold, that particular read threshold voltage is not a candidate for being an optimal read threshold voltage. As such, the syndrome weight estimation system 185 will stop the syndrome weight calculation once the syndrome weight threshold has been exceeded. The syndrome weight estimation system 185 will provide a notification to the ECC system 180 that the syndrome weight threshold was exceeded by the particular read threshold voltage. The syndrome weight estimation system 185 may also provide a predetermined syndrome weight value to the ECC system 180 that indicates that the particular read threshold voltage is not a candidate for being the optimal read threshold voltage.

Referring back to FIG. 1, in another example, the syndrome weight estimation system 185 may use inaccurate syndrome weight estimations when calculating syndrome weights for various read threshold voltages. For example, and as previously indicted, since the goal of the read threshold calibration operation is to search for read thresholds that provide the lowest syndrome weight, exact syndrome weight values may be less important compared with relative syndrome weight values (e.g., does a first read threshold voltage provide a lower syndrome weight when compared with a second read threshold voltage).

Accordingly, the syndrome weight estimation system 185 may process a part of the check nodes when calculating or estimating the syndrome weight. For example, when a read threshold calibration operation is initiated, the ECC system 180 may indicate or provide a syndrome weight estimation request, along with a check node count limit that indicates a maximum amount of check nodes to evaluate, to the syndrome weight estimation system 185. For example, the check node count limit may indicate that the ECC system wants to calculate the syndrome weight for half, or a certain number, of check nodes. This will reduce the latency and power consumption of the corresponding procedure by half (or based on the certain number of check nodes being analyzed) when compared with current solutions.

In response to receiving the syndrome weight estimation request and the check node count limit, the syndrome weight estimation system 185 traverses the bipartite graph until the number of check nodes analyzed reaches the check node count limit. Once the check node count limit has been reached, the syndrome weight estimation system 185 stops further syndrome weight calculations for the particular read threshold voltage and determines the syndrome weight associated with the read threshold voltage. The syndrome weight is then provided to the ECC system 180.

In response to receiving the syndrome weight for the particular read threshold voltage, the ECC system 180 marks or identifies the particular read threshold voltage as being a candidate for an optimal read threshold voltage or as not being a candidate for an optimal read threshold voltage. In an example, this determination is based, at least in part, on comparing the syndrome weight with previously calculated syndrome weights and/or subsequently determined syndrome weights for different read threshold voltages.

For example and referring to FIG. 2B, FIG. 2B illustrates a bipartite graph 210 that may be used in a parity check operation according to another example. Like the bipartite graph 200 shown in FIG. 2A, the bipartite graph 210 includes a number of variable nodes (e.g., variable nodes V ₁ – V ₁₃) and a number of check nodes (C ₁– C ₁₀). The variable nodes are connected to various check nodes using one or more edges.

During a parity check operation, a syndrome weight estimation system, such as the syndrome weight estimation system 185 (FIG. 1), determines, based on a check node count limit received from the ECC system, to analyze check nodes C ₁ through C ₅(represented by the shading). As each check node of the selected subset of check nodes is analyzed, an accumulated syndrome weight is determined. Once the requested amount of check nodes have been analyzed, the accumulated syndrome weight is provided to the ECC system.

When the ECC system receives the accumulated syndrome weight, the ECC system may compare the received syndrome weight to other syndrome weights to determine which read threshold voltage is comparably more optimal.

Referring back to FIG. 1, in yet another example, the syndrome weight estimation system 185 may combine the prior two operations or methods. For example, when a read threshold calibration operation is initiated, the ECC system 180 may provide a check node count limit and a syndrome weight threshold to the syndrome weight estimation system 185. When the check node count is reached, the syndrome weight estimation system 185 determines whether the syndrome weight is below the syndrome weight threshold. If the calculated syndrome weight for the subset of check nodes is below the syndrome weight threshold, the read threshold voltage may be an optimal read threshold voltage. As such, the syndrome weight estimation system 185 will continue to calculate the full syndrome weight and return it to the ECC system 180.

However, if the syndrome weight estimation system 185 determines that the syndrome weight is above the syndrome weight threshold after the subset of check nodes have been analyzed, the syndrome weight estimation system 185 will cease further syndrome weight calculations and provide notice to the ECC system 180 such as previously described.

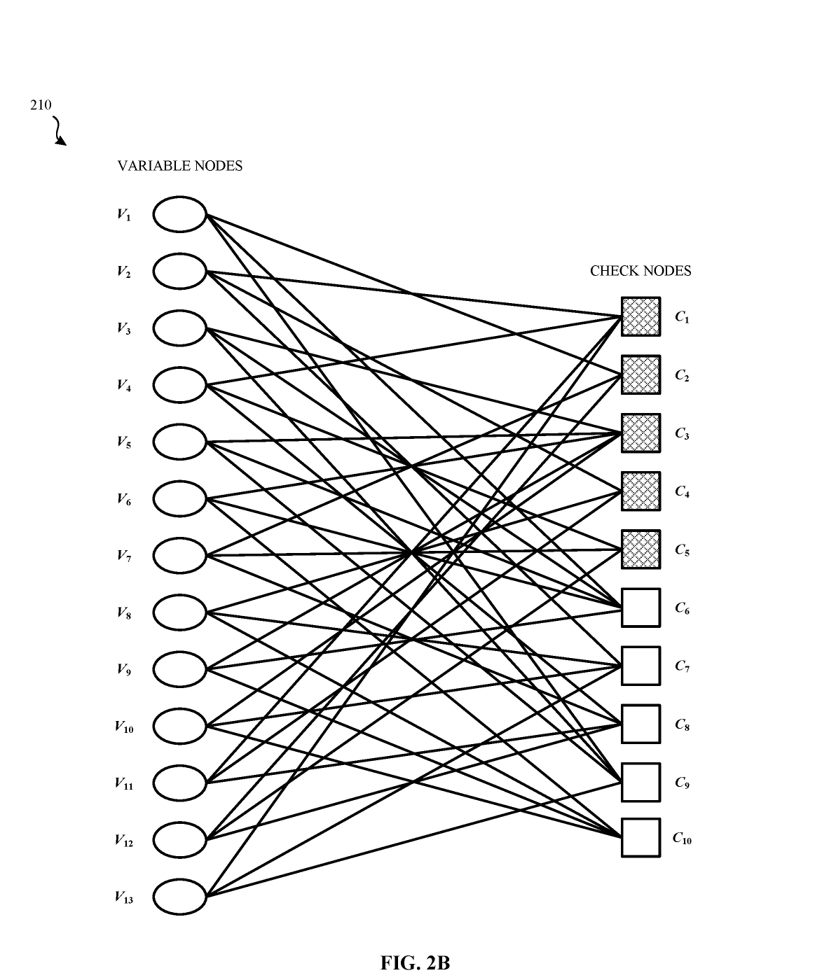

FIG. 3 illustrates a method 300 for estimating a syndrome weight of a read threshold voltage according to an example. In an example, the method 300 may be performed by a syndrome weight estimation system associated with a controller of a data storage device, such as, for example, the syndrome weight estimation system 185 shown and described with respect to FIG. 1.

In an example, the method 300 begins when a read threshold calibration operation is initiated (310). In an example, the read threshold calibration operation is initiated by a controller, an ECC system associated with the controller and/or the syndrome weight estimation system. In an example, the read threshold calibration operation is a BES operation such as previously described. However, in other examples, the method 300 may be executed as part of any operation in which a syndrome weight calculation is needed and/or required.

In response to the read threshold calibration operation being initiated, the syndrome weight estimation system receives (320) a syndrome weight estimation request. The syndrome weight estimation request may include a codeword that was read at a particular read threshold voltage. The syndrome weight estimation system also receives (330) a syndrome weight threshold. In response to receiving the request and the syndrome weight threshold, the syndrome weight estimation system executes (340) a parity check on the codeword to estimate a syndrome weight of the codeword.

Depending on the results of the parity check, the syndrome weight estimation system increments (350) an accumulated syndrome weight. The syndrome weight estimation system also determines (360) whether the accumulated syndrome weight is above the syndrome weight threshold. If the syndrome weight estimation system determines (360) the accumulated syndrome weight is above the syndrome weight threshold, the syndrome weight estimation system returns (380) the accumulated syndrome weight to the ECC system and the method 300 ends. The method 300 may then be repeated using another codeword associated with a different read threshold.

However, if the syndrome weight estimation system determines (360) that the accumulated syndrome weight is below the syndrome weight threshold, the syndrome weight estimation system determines (370) whether all of the check nodes in the parity check operation have been processed. If the syndrome weight estimation system determines (370) that all of the check nodes have been processed, the syndrome weight estimation system returns (380) the accumulated syndrome weight to the ECC system and the method 300 ends. However, if the syndrome weight estimation system determines (370) that all of the check nodes have not been processed, the next check node is selected (390) and the syndrome weight estimation system executes (340) a parity check on the next check node and operations 340 through 390 are repeated (as necessary/needed).

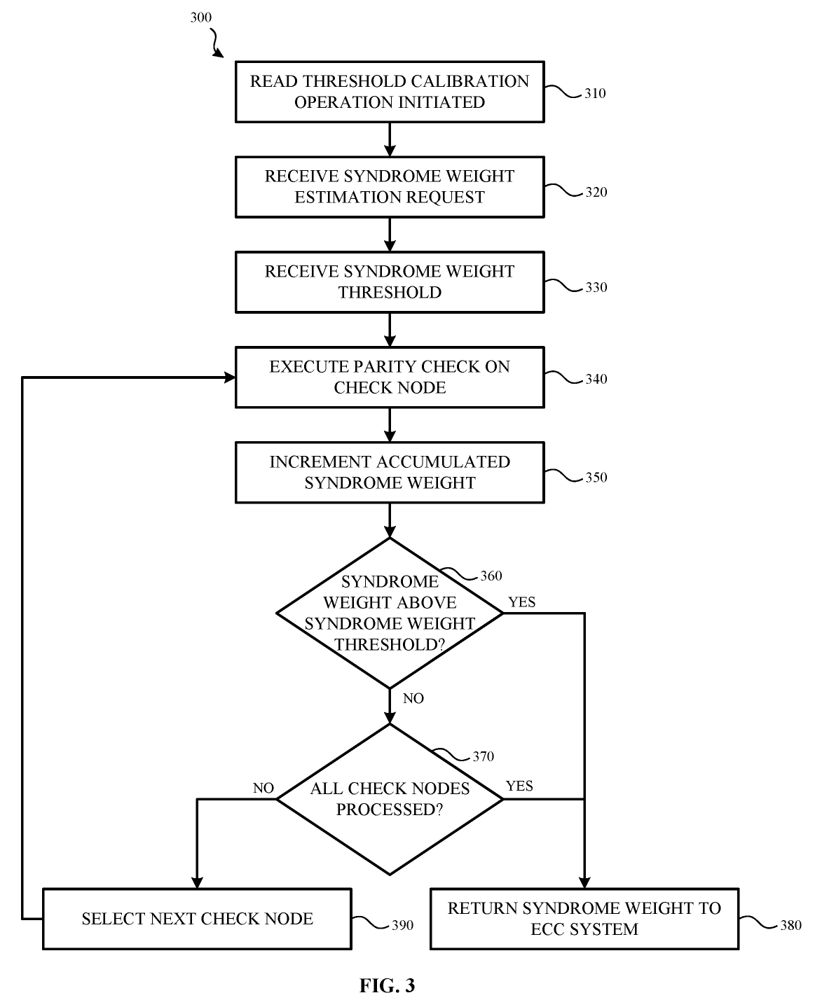

FIG. 4 illustrates a method 400 for estimating a syndrome weight of a read threshold voltage according to another example. In an example, the method 400 may be performed by a syndrome weight estimation system associated with a controller of a data storage device, such as, for example, the syndrome weight estimation system 185 shown and described with respect to FIG. 1.

In an example, the method 400 begins when a read threshold calibration operation is initiated (410). In an example, the read threshold calibration operation is initiated by a controller, an ECC system associated with the controller and/or the syndrome weight estimation system. In an example, the read threshold calibration operation is a BES operation such as previously described. However, in other examples, the method 400 may be executed as part of any operation in which a syndrome weight calculation is needed and/or required.

In response to the read threshold calibration operation being initiated, the syndrome weight estimation system receives (420) a syndrome weight estimation request. The syndrome weight estimation request may include a codeword that was read at a particular read threshold voltage. The syndrome weight estimation system also receives (430) a check node count limit that specifies a maximum number of check nodes that should be analyzed during the parity check and/or syndrome weight estimation operation. In response to receiving the request and the check node count limit, the syndrome weight estimation system executes (440) a parity check on the codeword.

Depending on the results of the parity check, the syndrome weight estimation system increments (450) an accumulated syndrome weight. The syndrome weight estimation system also determines (460) whether a number of analyzed check nodes exceeds the check node count limit. If the syndrome weight estimation system determines (460) that the number of analyzed check nodes is below the check node count limit, the next check node is selected (480) and the syndrome weight estimation system executes (440) the parity check on the next check node. The operations may then be repeated.

However, if the syndrome weight estimation system determines (460) that the number of analyzed check nodes is above the check node count limit, the syndrome weight estimation system returns (470) the accumulated syndrome weight to the ECC system and the method 300 ends.

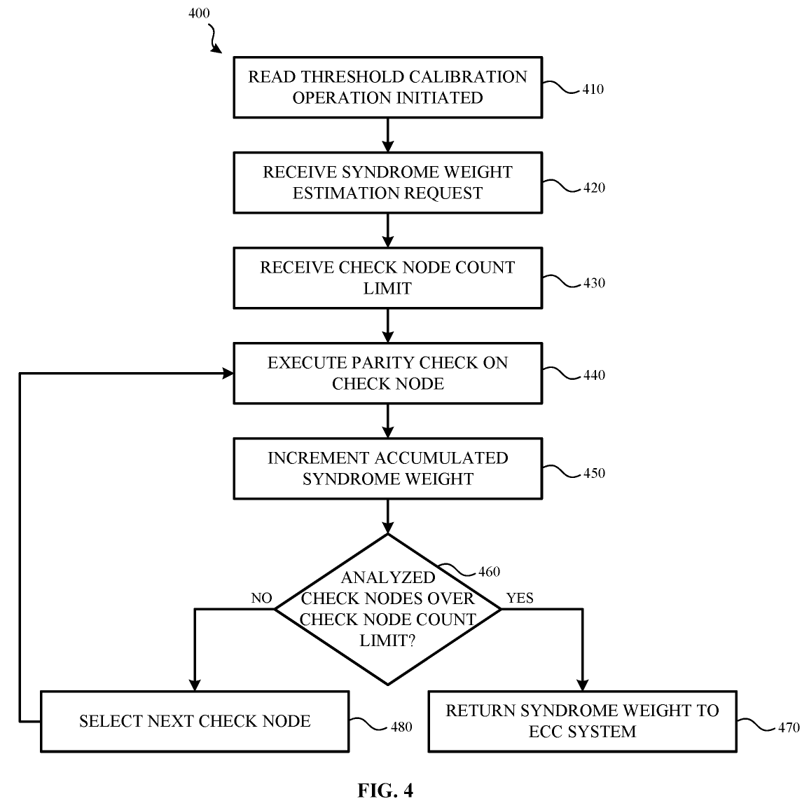

FIG. 5 illustrates a method 500 for estimating a syndrome weight of a read threshold voltage according to another example. In an example, the method 500 may be performed by a syndrome weight estimation system associated with a controller of a data storage device, such as, for example, the syndrome weight estimation system 185 shown and described with respect to FIG. 1.

In an example, the method 500 begins when a read threshold calibration operation is initiated (510). In an example, the read threshold calibration operation is initiated by a controller, an ECC system associated with the controller and/or the syndrome weight estimation system. In an example, the read threshold calibration operation is a BES operation such as previously described. However, in other examples, the method 500 may be executed as part of any operation in which a syndrome weight calculation is needed and/or required.

In response to the read threshold calibration operation being initiated, the syndrome weight estimation system receives (520) a syndrome weight estimation request. The syndrome weight estimation request may include a codeword that was read at a particular read threshold voltage. The syndrome weight estimation system also receives (530) a syndrome weight threshold and a check node count limit. In response to receiving the request, the syndrome weight threshold and the check node count limit, the syndrome weight estimation system executes (540) a parity check on a check node associated with the codeword and/or otherwise determines or estimates a syndrome weight of the codeword.

Depending on the results of the parity check, the syndrome weight estimation system increments (550) an accumulated syndrome weight. The syndrome weight estimation system also determines (560) whether a number of analyzed check nodes exceeds the check node count limit. If the syndrome weight estimation system determines (560) that the number of analyzed check nodes is below the check node count limit, the next check node is selected (570) and the syndrome weight estimation system executes (540) the parity check on the next check node. The operations may then be repeated.

However, if the syndrome weight estimation system determines (560) that the number of analyzed check nodes is above the check node count limit, the syndrome weight estimation system determines (580) whether the accumulated syndrome weight is below the syndrome weight threshold. If the syndrome weight estimation system determines (580) that the accumulated syndrome weight is below the syndrome weight threshold, the syndrome weight estimation system calculates the syndrome weight for all of the check nodes and provides the syndrome weight to the ECC system. The method 500 may then be repeated using another codeword and/or another read threshold voltage.

However, if the syndrome weight estimation system determines (580) that the accumulated syndrome weight is above the syndrome weight threshold, the syndrome weight estimation system returns (595) the estimated syndrome weight to the ECC system and the method 500 ends. However, the method 500 may also be repeated using another codeword associated with a different read threshold.

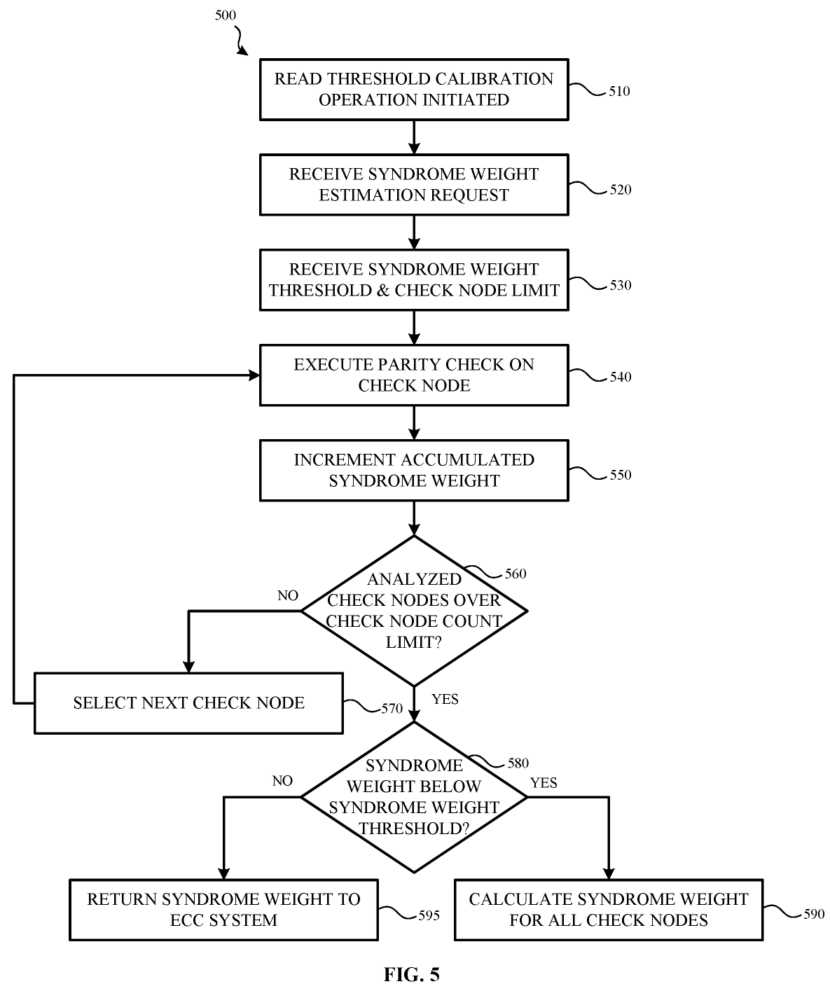

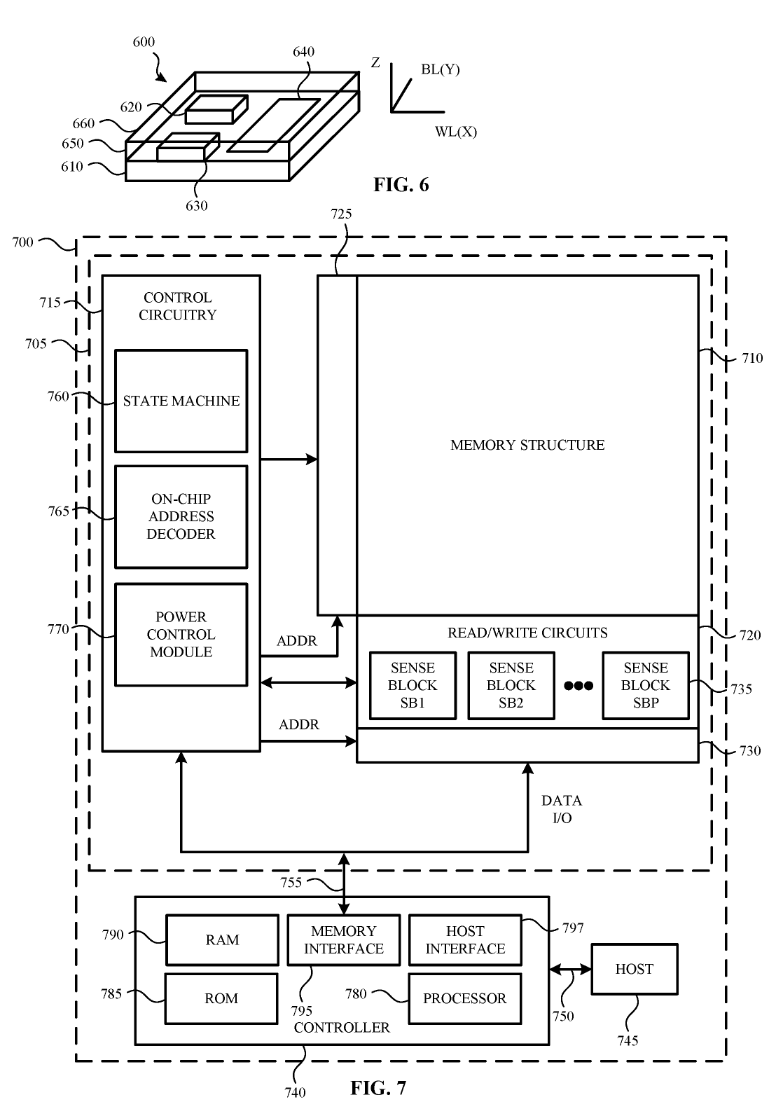

FIGS. 6-7 describe example storage devices that may be used with or otherwise implement the various features described herein. For example, the storage devices shown and described with respect to FIGS. 6-7 may include various systems and components that are similar to the systems and components shown and described with respect to FIG. 1. For example, the controller 740 shown and described with respect to FIG. 7 may be similar to the controller 150 of FIG. 1. Likewise, the memory dies 705 may be similar to the first memory die 165 and/or the second memory die 170 of FIG. 1.

FIG. 6 is a perspective view of a storage device 600 that includes three-dimensional (3D) stacked non-volatile memory according to an example. In this example, the storage device 600 includes a substrate 610. Blocks of memory cells are included on or above the substrate 610. The blocks may include a first block (BLK0 620) and a second block (BLK1 630). Each block may be formed of memory cells (e.g., non-volatile memory elements). The substrate 610 may also include a peripheral area 640 having support circuits that are used by the first block and the second block.

The substrate 610 may also carry circuits under the blocks, along with one or more lower metal layers which are patterned in conductive paths to carry signals from the circuits. The blocks may be formed in an intermediate region 650 of the storage device 600. The storage device may also include an upper region 660. The upper region 660 may include one or more upper metal layers that are patterned in conductive paths to carry signals from the circuits. Each block of memory cells may include a stacked area of memory cells. In an example, alternating levels of the stack represent word lines. While two blocks are depicted, additional blocks may be used and extend in the x-direction and/or the y-direction.

In an example, a length of a plane of the substrate 610 in the x-direction represents a direction in which signal paths for word lines or control gate lines extend (e.g., a word line or drain-end select gate (SGD) line direction) and the width of the plane of the substrate 610 in the y-direction represents a direction in which signal paths for bit lines extend (e.g., a bit line direction). The z-direction represents a height of the storage device 600.

FIG. 7 is a functional block diagram of a storage device 700 according to an example. In an example, the storage device 700 is the 3D stacked non-volatile storage device 600 shown and described with respect to FIG. 6. The components depicted in FIG. 7 may be electrical circuits. In an example, the storage device 700 includes one or more memory dies 705. Each memory die 705 includes a three-dimensional memory structure 710 of memory cells (e.g., a 3D array of memory cells), control circuitry 715, and read/write circuits 720. In another example, a two-dimensional array of memory cells may be used. The memory structure 710 is addressable by word lines using a first decoder 725 (e.g., a row decoder) and by bit lines using a second decoder 730 (e.g., a column decoder). The read/write circuits 720 may also include multiple sense blocks 735 including SB1, SB2, . . ., SBp (e.g., sensing circuitry) which allow pages of the memory cells to be read or programmed in parallel. The sense blocks 735 may include bit line drivers.

In an example, a controller 740 is included in the same storage device 700 as the one or more memory dies 705. In another example, the controller 740 is formed on a die that is bonded to a memory die 705, in which case each memory die 705 may have its own controller 740. In yet another example, a controller die controls all of the memory dies 705.

Commands and data may be transferred between a host 745 and the controller 740 using a data bus 750. Commands and data may also be transferred between the controller 740 and one or more of the memory dies 705 by way of lines 755. In one example, the memory die 705 includes a set of input and/or output (I/O) pins that connect to lines 755.

The memory structure 710 may also include one or more arrays of memory cells. The memory cells may be arranged in a three-dimensional array or a two-dimensional array. The memory structure 710 may include any type of non-volatile memory that is formed on one or more physical levels of arrays of memory cells having an active area disposed above a silicon substrate. The memory structure 710 may be in a non-volatile memory device having circuitry associated with the operation of the memory cells, whether the associated circuitry is above or within the substrate.

The control circuitry 715 works in conjunction with the read/write circuits 720 to perform memory operations (e.g., erase, program, read, and others) on the memory structure 710. The control circuitry 715 may include registers, ROM fuses, and other devices for storing default values such as base voltages and other parameters.

The control circuitry 715 may also include a state machine 760, an on-chip address decoder 765 and a power control module 770. The state machine 760 may provide chip-level control of various memory operations. The state machine 760 may be programmable by software. In another example, the state machine 760 does not use software and is completely implemented in hardware (e.g., electrical circuits). The on-chip address decoder 765 may provide an address interface between addresses used by host 745 and/or the controller 740 to a hardware address used by the first decoder 725 and the second decoder 730.

The power control module 770 may control power and voltages that are supplied to the word lines and bit lines during memory operations. The power control module 770 may include drivers for word line layers in a 3D configuration, select transistors (e.g., SGS and SGD transistors) and source lines. The power control module 770 may include one or more charge pumps for creating voltages.

The control circuitry 715, the state machine 760, the on-chip address decoder 765, the first decoder 725, the second decoder 730, the power control module 770, the sense blocks 735, the read/write circuits 720, and/or the controller 740 may be considered one or more control circuits and/or a managing circuit that perform some or all of the operations described herein.

In an example, the controller 740, is an electrical circuit that may be on-chip or off-chip. Additionally, the controller 740 may include one or more processors 780, ROM 785, RAM 790, memory interface 795, and host interface 797, all of which may be interconnected. In an example, the one or more processors 780 is one example of a control circuit. Other examples can use state machines or other custom circuits designed to perform one or more functions. Devices such as ROM 785 and RAM 790 may include code such as a set of instructions. One or more of the processors 780 may be operable to execute the set of instructions to provide some or all of the functionality described herein.

Alternatively or additionally, one or more of the processors 780 may access code from a memory device in the memory structure 710, such as a reserved area of memory cells connected to one or more word lines. The memory interface 795, in communication with ROM 785, RAM 790, and one or more of the processors 780, may be an electrical circuit that provides an electrical interface between the controller 740 and the memory die 705. For example, the memory interface 795 may change the format or timing of signals, provide a buffer, isolate from surges, latch I/O, and so forth.

The one or more processors 780 may issue commands to control circuitry 715, or any other component of memory die 705, using the memory interface 795. The host interface 797, in communication with the ROM 785, the RAM 790, and the one or more processors 780, may be an electrical circuit that provides an electrical interface between the controller 740 and the host 745. For example, the host interface 797 may change the format or timing of signals, provide a buffer, isolate from surges, latch I/O, and so on. Commands and data from the host 745 are received by the controller 740 by way of the host interface 797. Data sent to the host 745 may be transmitted using the data bus 750.

Multiple memory elements in the memory structure 710 may be configured so that they are connected in series or so that each element is individually accessible. By way of a non-limiting example, flash memory devices in a NAND configuration (e.g., NAND flash memory) typically contain memory elements connected in series. A NAND string is an example of a set of series-connected memory cells and select gate transistors.

A NAND flash memory array may also be configured so that the array includes multiple NAND strings. In an example, a NAND string includes multiple memory cells sharing a single bit line and are accessed as a group. Alternatively, memory elements may be configured so that each memory element is individually accessible (e.g., a NOR memory array). The NAND and NOR memory configurations are examples and memory cells may have other configurations.

The memory cells may be arranged in the single memory device level in an ordered array, such as in a plurality of rows and/or columns. However, the memory elements may be arrayed in non-regular or non-orthogonal configurations, or in structures not considered arrays.

In an example, a 3D memory structure may be vertically arranged as a stack of multiple 2D memory device levels. As another non-limiting example, a 3D memory array may be arranged as multiple vertical columns (e.g., columns extending substantially perpendicular to the major surface of the substrate, such as in the y direction) with each column having multiple memory cells. The vertical columns may be arranged in a two-dimensional arrangement of memory cells, with memory cells on multiple vertically stacked memory planes. Other configurations of memory elements in three dimensions can also constitute a 3D memory array.

In another example, in a 3D NAND memory array, the memory elements may be coupled together to form vertical NAND strings that traverse across multiple horizontal memory device levels. Other 3D configurations can be envisioned wherein some NAND strings contain memory elements in a single memory level while other strings contain memory elements which span through multiple memory levels. 3D memory arrays may also be designed in a NOR configuration and in a ReRAM configuration.

Based on the above, examples of the present disclosure describe a method, comprising: receiving, from a requesting system, a syndrome weight estimation request, the syndrome weight estimation request being associated with a particular read threshold voltage combination and a codeword; receiving a parameter associated with the syndrome weight estimation request; executing a parity check on a check node associated with the codeword; determining whether the parameter associated with the syndrome weight estimation request is satisfied based, at least in part, on the parity check on the check node; and based, at least in part, on determining that the parameter associated with the syndrome weight estimation request is satisfied: stopping execution of additional parity checks; and returning an estimated syndrome weight to the requesting system. In an example, the parameter associated with the syndrome weight estimation request is a syndrome weight threshold. In an example, the method also includes incrementing an accumulated syndrome weight in response to the execution of the parity check; and comparing the accumulated syndrome weight to the syndrome weight threshold. In an example, the parameter associated with the syndrome weight estimation request is a check node count limit. In an example, the method also includes incrementing an accumulated syndrome weight in response to the execution of the parity check; incrementing a check node count in response to executing the parity check on the check node; and comparing the check node count to the check node count limit. In an example, the parameter associated with the syndrome weight estimation request is one or more of a syndrome weight threshold and a check node count limit. In an example, the method also includes incrementing an accumulated syndrome weight in response to the execution of the parity check; incrementing a check node count in response to executing the parity check on the check node; comparing the check node count to the check node count limit; and comparing the accumulated syndrome weight to the syndrome weight threshold based, at least in part, on determining the check node count exceeds the check node count limit. In an example, the method also includes calculating a syndrome weight for additional check nodes based, at least in part, on determining the accumulated syndrome weight is above the syndrome weight threshold. In an example, the method also includes returning the estimated syndrome weight to the requesting system based, at least in part, on determining the accumulated syndrome weight is below the syndrome weight threshold.

Other examples describe a data storage device, comprising: a controller; and a syndrome weight estimation system associated with the controller and operable to: receive a syndrome weight estimation request; receive a parameter associated with the syndrome weight estimation request; initiate execution of a syndrome weight determination operation; determine whether the parameter associated with the syndrome weight estimation request is satisfied during the execution of the syndrome weight determination operation; and based, at least in part, on determining that the parameter associated with the syndrome weight estimation request is satisfied: stopping execution the syndrome weight determination operation; and returning an estimated syndrome weight to a requesting device. In an example, the syndrome weight estimation request is part of a read threshold calibration operation. In an example, the parameter associated with the syndrome weight estimation request is a syndrome weight threshold. In an example, the parameter associated with the syndrome weight estimation request is a check node count limit. In an example, the parameter associated with the syndrome weight estimation request is a syndrome weight threshold and a check node count limit.

Examples also describe a data storage device, comprising: means for receiving a syndrome weight estimation request; means for receiving a parameter associated with the syndrome weight estimation request; means for executing a syndrome weight determination operation; means for determining whether the parameter associated with the syndrome weight estimation request is satisfied during the syndrome weight determination operation; and means for stopping execution of the syndrome weight determination operation, wherein the means for stopping the execution of the syndrome weight determination operation stops the execution of the syndrome weight determination operation based, at least in part, on a determination that the parameter associated with the syndrome weight estimation request is satisfied. In an example, the data storage device also includes means for returning an estimated syndrome weight to a requesting device. In an example, the parameter associated with the syndrome weight estimation request is a syndrome weight threshold. In an example, the data storage device also includes means for incrementing an accumulated syndrome weight during execution of the syndrome weight determination operation; and means for comparing the accumulated syndrome weight to the syndrome weight threshold. In an example, the parameter associated with the syndrome weight estimation request is a check node count limit. In an example, the parameter associated with the syndrome weight estimation request is a syndrome weight threshold and a check node count limit

One of ordinary skill in the art will recognize that the technology described herein is not limited to a single specific memory structure, but covers many relevant memory structures within the spirit and scope of the technology as described herein and as understood by one of ordinary skill in the art.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

References to an element herein using a designation such as "first," "second," and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method, comprising:
receiving, from a requesting system, a syndrome weight estimation request, the syndrome weight estimation request being associated with a particular read threshold voltage combination and a codeword;
receiving a parameter associated with the syndrome weight estimation request;
executing a parity check on a check node associated with the codeword;
determining whether the parameter associated with the syndrome weight estimation request is satisfied based, at least in part, on the parity check on the check node; and
based, at least in part, on determining that the parameter associated with the syndrome weight estimation request is satisfied:
stopping execution of additional parity checks; and
returning an estimated syndrome weight to the requesting system.

2. The method of claim 1, wherein the parameter associated with the syndrome weight estimation request is a syndrome weight threshold.

3. The method of claim 2, further comprising:
incrementing an accumulated syndrome weight in response to the execution of the parity check; and
comparing the accumulated syndrome weight to the syndrome weight threshold.

4. The method of claim 1, wherein the parameter associated with the syndrome weight estimation request is a check node count limit.

5. The method of claim 4, further comprising:
incrementing an accumulated syndrome weight in response to the execution of the parity check;
incrementing a check node count in response to executing the parity check on the check node; and
comparing the check node count to the check node count limit.

6. The method of claim 1, wherein the parameter associated with the syndrome weight estimation request is one or more of a syndrome weight threshold and a check node count limit.

7. The method of claim 6, further comprising:
incrementing an accumulated syndrome weight in response to the execution of the parity check;
incrementing a check node count in response to executing the parity check on the check node;
comparing the check node count to the check node count limit; and
comparing the accumulated syndrome weight to the syndrome weight threshold based, at least in part, on determining the check node count exceeds the check node count limit.

8. The method of claim 7, further comprising calculating a syndrome weight for additional check nodes based, at least in part, on determining the accumulated syndrome weight is above the syndrome weight threshold.

9. The method of claim 7, further comprising returning the estimated syndrome weight to the requesting system based, at least in part, on determining the accumulated syndrome weight is below the syndrome weight threshold.

10. A data storage device, comprising:
a controller; and
a syndrome weight estimation system associated with the controller and operable to:
receive a syndrome weight estimation request;
receive a parameter associated with the syndrome weight estimation request;
initiate execution of a syndrome weight determination operation;
determine whether the parameter associated with the syndrome weight estimation request is satisfied during the execution of the syndrome weight determination operation; and
based, at least in part, on determining that the parameter associated with the syndrome weight estimation request is satisfied:
stopping execution the syndrome weight determination operation; and
returning an estimated syndrome weight to a requesting device.

11. The data storage device of claim 10, wherein the syndrome weight estimation request is part of a read threshold calibration operation.

12. The data storage device of claim 10, wherein the parameter associated with the syndrome weight estimation request is a syndrome weight threshold.

13. The data storage device of claim 10, wherein the parameter associated with the syndrome weight estimation request is a check node count limit.

14. The data storage device of claim 10, wherein the parameter associated with the syndrome weight estimation request is a syndrome weight threshold and a check node count limit.

15. A data storage device, comprising:
means for receiving a syndrome weight estimation request;
means for receiving a parameter associated with the syndrome weight estimation request;
means for executing a syndrome weight determination operation;
means for determining whether the parameter associated with the syndrome weight estimation request is satisfied during the syndrome weight determination operation; and
means for stopping execution of the syndrome weight determination operation, wherein the means for stopping the execution of the syndrome weight determination operation stops the execution of the syndrome weight determination operation based, at least in part, on a determination that the parameter associated with the syndrome weight estimation request is satisfied.

16. The data storage device of claim 15, further comprising means for returning an estimated syndrome weight to a requesting device.

17. The data storage device of claim 15, wherein the parameter associated with the syndrome weight estimation request is a syndrome weight threshold.

18. The data storage device of claim 17, further comprising:
means for incrementing an accumulated syndrome weight during execution of the syndrome weight determination operation; and
means for comparing the accumulated syndrome weight to the syndrome weight threshold.

19. The data storage device of claim 17, wherein the parameter associated with the syndrome weight estimation request is a check node count limit.

20. The data storage device of claim 17, wherein the parameter associated with the syndrome weight estimation request is a syndrome weight threshold and a check node count limit.
